(19) United States
(12) Patent Application Publication
(10) Pub. No.: US 2025/0275069 A1
(43) Pub. Date: Aug. 28, 2025

(54) SLIDABLE DISPLAY DEVICE

(71) Applicant: LG Display Co., Ltd., Seoul (KR)

(72) Inventors: MiJin Han, Seoul (KR); Daeyun Kim, Seoul (KR); HoSung Park, Paju-si (KR)

(73) Assignee: LG Display Co., Ltd., Seoul (KR)

(21) Appl. No.: 18/821,899

(22) Filed: Aug. 30, 2024

(30) Foreign Application Priority Data
Feb. 26, 2024 (KR) 10-2024-0027190

(51) Int. Cl. H05K 5/02; B60R 11/00; B60R 11/02

(52) U.S. Cl. CPC H05K 5/0217; B60R 11/0235; B60R 2011/0028; B60R 2011/0043; B60R 2011/0084; B60R 2011/0092

(57) ABSTRACT

A slidable display device in one example includes a display panel assembly, a mounting frame, and a guide member tiltably connected to the mounting frame. The guide member can be configured to support the display panel assembly as the display panel assembly moves between a first position and a second position with respect to the mounting frame. The guide member can be configured to bend the display panel assembly as the display panel assembly moves from the first position to the second position so that a first portion of the display panel assembly is tilted downward.

### CROSS-REFERENCE TO RELATED APPLICATIONS

This application claims priority to Korean Patent Application No. 10-2024-0027190 filed on Feb. 26, 2024, in the Korean Intellectual Property Office, the entire contents of which is hereby expressly incorporated by reference into the present application.

### BACKGROUND

### Field

The present disclosure relates to a display device, and more particularly, to a slidable display device which can display images even while sliding between a first position and a second position.

### Discussion of the Related Art

Display devices employed as a monitor of a computer, a TV, a mobile phone or the like may include an organic light emitting display (OLED) that emits light by itself, and a liquid crystal display (LCD) that requires a separate light source.

Such display devices are being used in more and more applications, including computer monitors, televisions, and personal portable devices, as well as in vehicles. Accordingly, research is ongoing to develop display devices having a larger display area while reducing the volume of the display devices.

Further, a slidable display device is attracting attention as a next generation display device. Such a slidable display device is manufactured by forming a display part and lines on a flexible substrate made of a flexible material, such as plastic, so that it can display images even when it is expanded or contracted in a sliding manner. That is, the slidable display device can have a display area that is active while it is sliding between an exposed state and a retracted state.

### SUMMARY OF THE DISCLOSURE

An object to be achieved by the present disclosure is to provide a slidable display device mounted on a roof panel of a vehicle to display images.

Another object to be achieved by the present disclosure is to provide a slidable display device whose display panel is extended out of the inside of a roof panel to display images.

Yet another object to be achieved by the present disclosure is to provide a slidable display device whose disposition angle can be controlled in a state in which a display panel is slid.

Objects of the embodiments of the present disclosure are not limited to the above-mentioned objects, and other objects, which are not mentioned above, can be clearly understood by those skilled in the art from the following descriptions.

According to an aspect of the present disclosure, a slidable display device comprises a mounting frame, a display panel assembly movably coupled to the mounting frame, and a guide member which is tiltably coupled to the mounting frame, supports the display panel assembly, and guides movement of the display panel assembly, wherein the guide member is configured to bend at least a part of the display panel assembly while being tilted.

Other detailed matters of the embodiments are included in the detailed description and the drawings.

According to the present disclosure, a slidable display device mounted on a roof panel of a vehicle can display images on a portion of the display device extending to the inside of the vehicle while it is slid.

According to the present disclosure, the slidable display device can display images while it is being extended from inside to outside the roof panel.

According to the present disclosure, the slidable display device can display images at a position desired by a user by adjusting a take-out angle of a display panel assembly.

According to the present disclosure, the stability of the display panel assembly can be secured while the slidable display device is slid.

According to the present disclosure, the durability of the display panel assembly can be enhanced while the slidable display device is not used.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1A is a perspective view schematically illustrating a slidable display device mounted on a roof panel of a vehicle according to an embodiment of the present disclosure;

FIG. 1B is a bottom perspective view schematically illustrating the slidable display device mounted on the roof panel of the vehicle according to an embodiment of the present disclosure;

FIG. 2A is a perspective view illustrating a structure of the slidable display device according to an embodiment of the present disclosure;

FIG. 2B is a bottom perspective view illustrating the structure of the slidable display device according to an embodiment of the present disclosure;

FIG. 3 is a side view of the slidable display device according to an embodiment of the present disclosure;

FIG. 4A is a side view illustrating a structure of a guide member according to an embodiment of the present disclosure;

FIG. 4B is a side view illustrating a guide driver being tilted according to an embodiment of the present disclosure;

FIG. 4C is a side view of the guide support being deployed according to an embodiment of the present disclosure;

FIG. 5 is an exploded perspective view of the slidable display device according to an embodiment of the present disclosure;

FIG. 6A is a perspective view of a guide member according to an embodiment of the present disclosure;

FIG. 6B is a perspective view illustrating a guide driver which is bent according to an embodiment of the present disclosure;

FIG. 6C is an enlarged perspective view illustrating a portion where a guide body is connected to an opening and closing plate according to an embodiment of the present disclosure;

FIG. 7A is a bottom perspective view of a guide support which is deployed according to an embodiment of the present disclosure;

FIG. 7B is an exploded perspective view of the guide support according to an embodiment of the present disclosure;

FIG. 8A is a perspective view illustrating a structure of a panel transfer unit according to an embodiment of the present disclosure;

FIG. 8B is an exploded perspective view illustrating the structure of the panel transfer unit according to an embodiment of the present disclosure;

FIG. 9 is an exploded perspective view of a display panel assembly according to an embodiment of the present disclosure;

FIG. 10A is a perspective view of the display panel assembly which is accommodated according to an embodiment of the present disclosure;

FIG. 10B is a bottom perspective view of the display panel assembly which is accommodated according to an embodiment of the present disclosure;

FIG. 11A is a perspective view of the display panel assembly which is bent according to an embodiment of the present disclosure;

FIG. 11B is a bottom perspective view of the display panel assembly which is bent according to an embodiment of the present disclosure;

FIG. 12A is a perspective view illustrating that a display panel of the display panel assembly is moved and exposed to the outside of a roof panel according to an embodiment of the present disclosure; and

FIG. 12B is a bottom perspective view illustrating that the display panel of the display panel assembly is moved and exposed to the outside of the roof panel according to an embodiment of the present disclosure.

### DETAILED DESCRIPTION OF THE EMBODIMENTS

The embodiments described herein can be variously modified. Specific embodiments are described in the drawings and can be described in detail in the detailed description. It should be understood, however, that the specific embodiments disclosed in the accompanying drawings are only intended to facilitate an understanding of the various embodiments of the present disclosure. Therefore, it is to be understood that the technical idea of the present disclosure is not limited by the specific embodiments disclosed in the accompanying drawings, but the present disclosure should be understood to include all equivalents or alternatives included in the spirit and technical scope of the present disclosure.

Terms including ordinals, such as first, second, etc., can be used to describe various elements, but such elements are not limited to the above terms. The above terms are used only for the purpose of distinguishing one component from another.

It will be further understood that the terms “comprises” and/or “comprising,” or “includes” and/or “including,” or “has” and/or “having” when used in this specification, specify the presence of stated features, integers, steps, operations, elements, components and/or groups thereof, but do not preclude the presence or addition of one or more other features, integers, steps, operations, elements, components and/or groups thereof. When a component is “linked”, “coupled”, or “connected” to another component, the component can be directly linked or connected to the other component. However, unless specifically stated otherwise, it should be understood that a third component can be interposed between the components which can be indirectly linked or connected.

A “module” or a “unit” for control elements used in the present specification performs at least one function or operation. Further, the “module” or the “unit” can perform functions or operations by hardware, software, or a combination of hardware and software. Further, a plurality of “modules” or a plurality of “units”, other than a “module” or a “unit” that is to be performed in specific hardware or performed in at least one processor, can be integrated into at least one module. The singular forms “a,” “an,” and “the” include plural expressions unless the context clearly dictates otherwise.

The use of “exemplary” in the present disclosure means to serve as an example as opposed to identifying a preferred embodiment.

Besides, in the following description of the present disclosure, the detailed description of known functions and configurations incorporated herein will be omitted when it can make the subject matter of the present disclosure rather unclear.

Hereinafter, various embodiments of the present disclosure will be described in detail with reference to the accompanying drawings. All the components of each slidable display device according to all embodiments of the present disclosure are operatively coupled and configured.

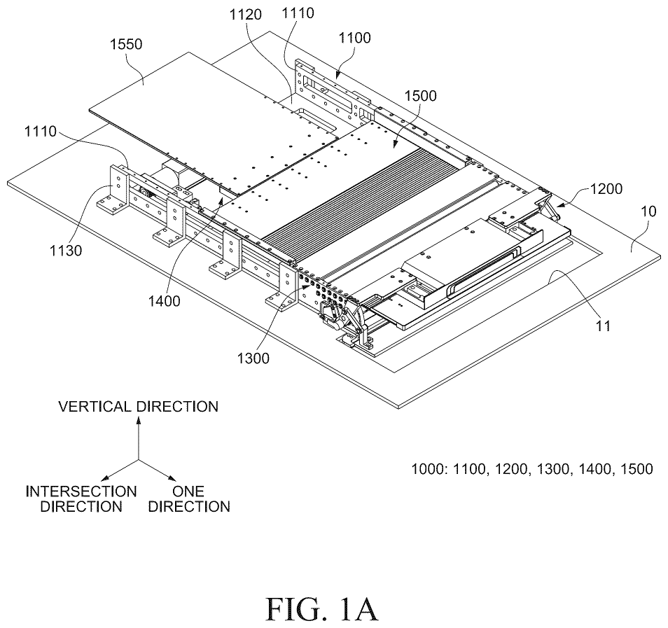

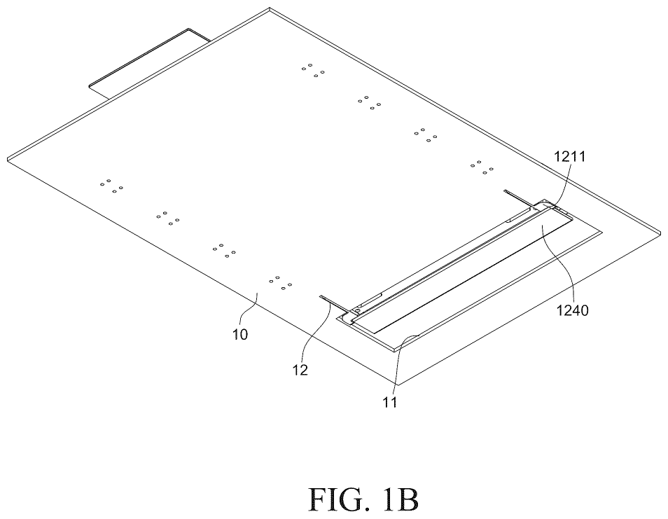

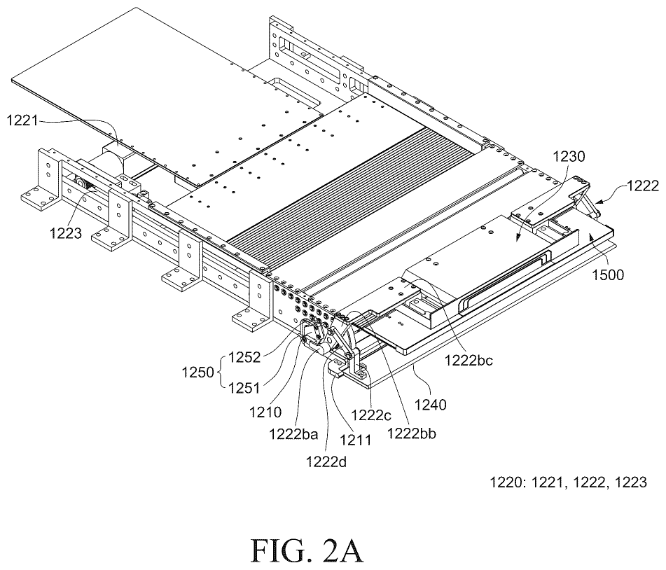

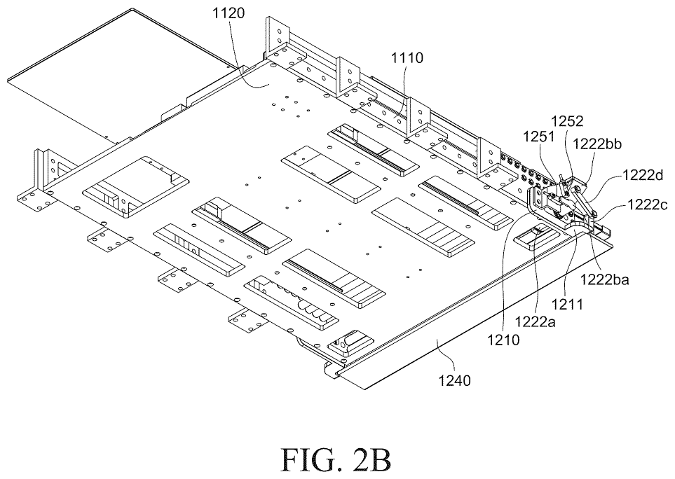

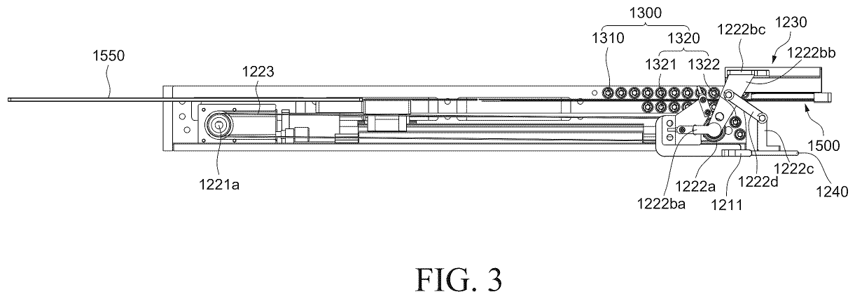

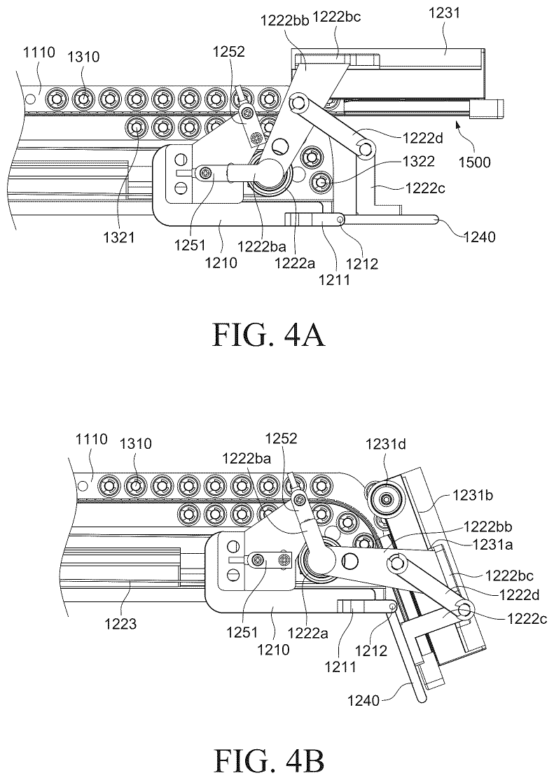

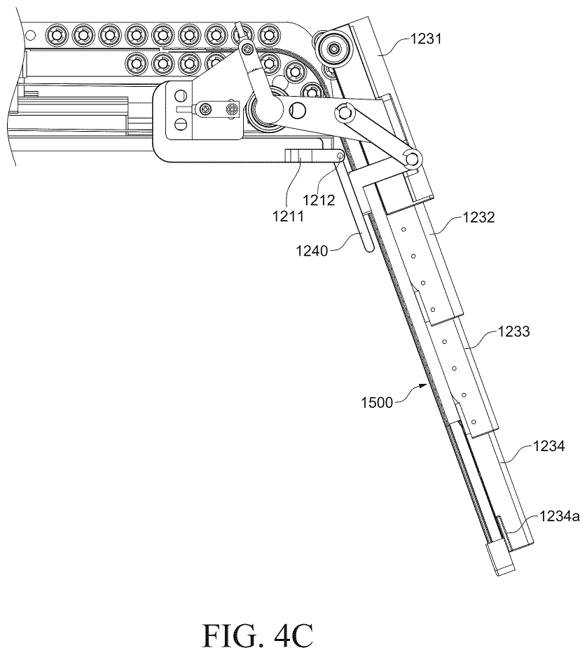

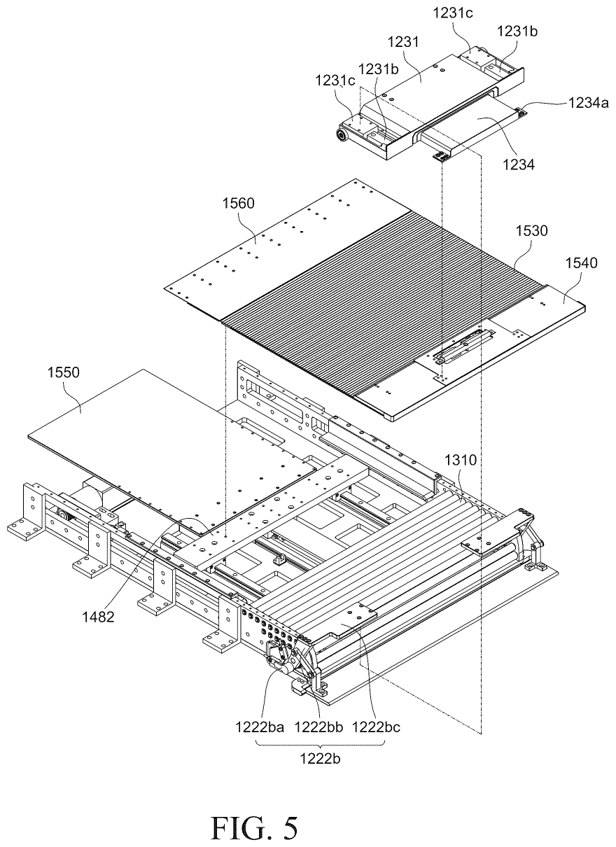

FIG. 1A is a schematic perspective view illustrating a slidable display device mounted on a roof panel of a vehicle according to an embodiment of the present disclosure. FIG. 1B is a bottom perspective view schematically illustrating the slidable display device mounted on the roof panel of the vehicle according to an embodiment of the present disclosure. FIG. 2A is a perspective view illustrating a structure of the slidable display device according to an embodiment of the present disclosure. FIG. 2B is a bottom perspective view illustrating the structure of the slidable display device according to an embodiment of the present disclosure. FIG. 3 is a side view of the slidable display device according to an embodiment of the present disclosure. FIG. 4A is a side view illustrating a structure of a guide member according to an embodiment of the present disclosure. FIG. 4B is a side view illustrating a guide driver being tilted according to an embodiment of the present disclosure. FIG. 4C is a side view of the guide support being deployed according to an embodiment of the present disclosure. FIG. 5 is an exploded perspective view of the slidable display device according to an embodiment of the present disclosure.

Referring to FIG. 1A through FIG. 5, a structure of a slidable display device 1000 according to an embodiment of the present disclosure will be described.

The slidable display device 1000 according to an embodiment of the present disclosure can be installed between an outer plate of a vehicle and a roof panel 10 of the vehicle disposed adjacent to the outer plate and under the outer plate.

The roof panel 10 of the vehicle includes an opening 11 penetrating in a vertical direction (see FIG. 1A). The opening 11 has a predetermined width along one direction along which the slidable display device 1000 extends (see FIG. 1A) and extends along an intersection direction (orthogonal to the one direction in a horizontal plane) (see FIG. 1A).

A display panel assembly 1500 of the slidable display device 1000 can be accommodated between the outer plate and the roof panel 10 of the vehicle or can slide and extend to the inside of the vehicle through the opening 11.

Further, the roof panel 10 of the vehicle includes slits 12 respectively extending from both sides of the opening 11 along the one direction.

The slidable display device 1000 can also be applied to other objects with roofs in addition to the roof panel 10 of the vehicle.

The slidable display device 1000 includes a mounting frame 1100, a guide member 1200, a roller unit 1300, a panel transfer unit 1400, and the display panel assembly 1500.

The mounting frame 1100 is disposed between the outer plate of the vehicle and the roof panel 10. Further, the guide member 1200, the roller unit 1300, and the panel transfer unit 1400 are mounted on the mounting frame 1100.

Referring to FIG. 1A through FIG. 2B, the mounting frame 1100 includes at least one first support frame 1110, a second support frame 1120, and at least one fixing bracket 1130.

A plurality (e.g., a pair) of first support frame 1110 is provided and spaced apart from each other on the roof panel 10 along the intersection direction. Each of the plurality of first support frames 1110 disposed on the roof panel 10 is supported on the roof panel 10 by the fixing bracket 1130.

Further, an end of the first support frame 1110 is coupled to a guide body 1210 of the guide member 1200.

Further, one end of the first support frame 1110 has a rounded surface at an upper portion thereof.

The second support frame 1120 is mounted on the roof panel 10 and serves to connect the plurality of first support frames 1110. The first support frame 1110 is supported on the second support frame 1120. The second support frame 1120 extends in the intersection direction and has a plate shape having a predetermined width along the one direction.

The fixing bracket 1130 is installed on the roof panel 10 and supports the plurality of first support frames 1110. A plurality of fixing brackets 1130 is provided and fixed to outer surfaces of the plurality of first support frames 1110. A part of the fixing bracket 1130 extends in the vertical direction (see FIG. 1A) and the other part extends in the intersection direction.

A mounting bracket configured to fix the first support frame 1110 to the outer plate of the vehicle can be included in the mounting frame 1100. The mounting bracket can be fixed to an inner surface of the first support frame 1110. A part of the mounting bracket can extend in the vertical direction and another part can extend in the intersection direction.

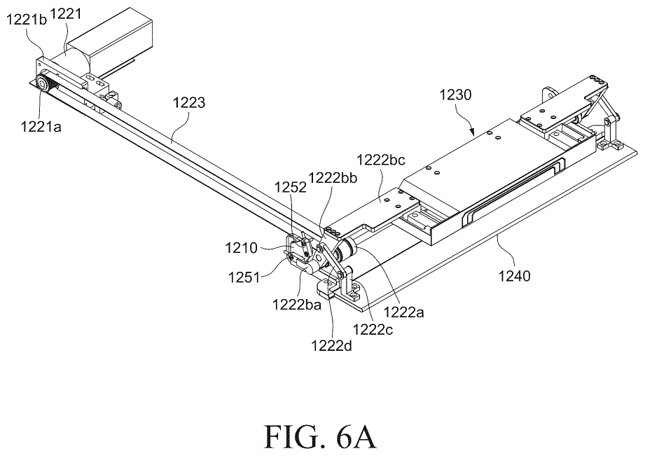

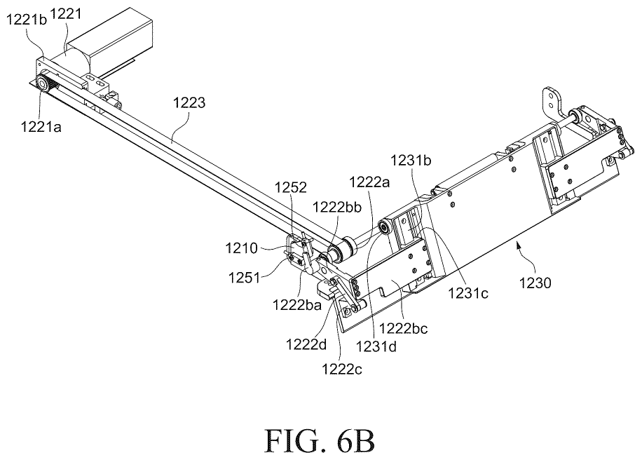

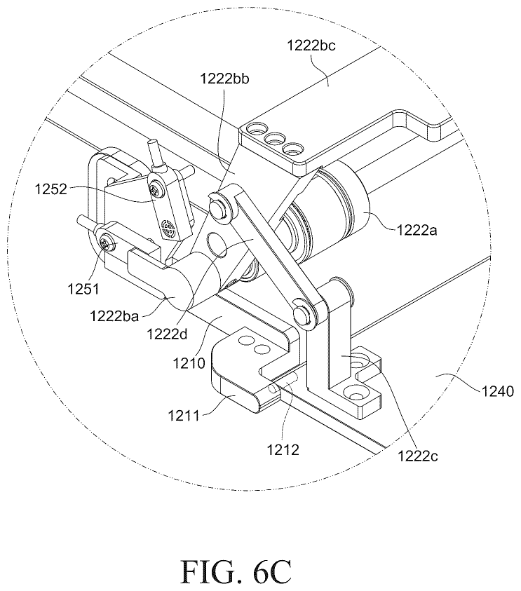

FIG. 6A is a perspective view of a guide member according to an embodiment of the present disclosure. FIG. 6B is a perspective view illustrating a guide driver which is bent according to an embodiment of the present disclosure. FIG. 6C is an enlarged perspective view illustrating a portion where a guide body is connected to an opening and closing plate according to an embodiment of the present disclosure.

Referring to FIG. 1A through FIG. 6C, the guide member 1200 is tiltably coupled to the mounting frame 1100, supports the display panel assembly 1500, and guides movement of the display panel assembly 1500. The guide member 1200 is configured to bend at least a part of the display panel assembly 1500 while the guide member 1200 is being tilted.

The guide member 1200 is configured to be tilted between an angle at which the display panel assembly 1500 is horizontally disposed and an angle at which a part of the display panel assembly 1500 is extended below the mounting frame 1100.

The guide member 1200 includes at least one guide body 1210, a guide driver 1220, a guide support 1230, an opening and closing plate 1240, and a sensor 1250.

A plurality of guide bodies 1210 is provided, disposed at an end of the first support frame 1110, and coupled to an outer side surface of the first support frame 1110. A lower portion of the guide body 1210 is disposed in the slit 12 of the roof panel 10. At least one of the guide bodies 1210 is equipped with the guide driver 1220 and the sensor 1250.

Further, the guide body 1210 includes support protrusions 1211 and insertion protrusions 1212 to rotatably support the opening and closing plate 1240. The support protrusions 1211 and the insertion protrusions 1212 of the plurality of guide bodies 1210 rotatably support opposite sides of the opening and closing plate 1240.

A part of the support protrusion 1211 extends from a lower portion of the guide body 1210 along the intersection direction, and the other part extends along the one direction and protrudes toward the front of the first support frame 1110. The support protrusions 1211 are disposed in the opening 11. For example, ends of the support protrusions 1211 can extend in the opening 11.

The insertion protrusion 1212 protrudes along the intersection direction in the other part of the support protrusion 1211. The insertion protrusions 1212 are inserted into grooves formed in the opening and closing plate 1240. The opening and closing plate 1240 is rotatably coupled to the support protrusions 1211 by the insertion protrusions 1212.

The support protrusions 1211 disposed in the opening 11 support the opening and closing plate 1240 through the insertion protrusions 1212. Therefore, when the opening and closing plate 1240 is not rotated by the guide driver 1220, the opening and closing plate 1240 is maintained horizontally with respect to the roof panel 10. Thus, the aesthetics of the interior of the vehicle can be improved. Further, the support protrusions 1211 support the opening and closing plate 1240 at positions where the support protrusions 1211 protrude toward the front of the first support frame 1110. Thus, the opening and closing plate 1240 can be rotated without interference with the first support frame 1110.

The guide driver 1220 is installed on the mounting frame 1100, operatively connected to the guide body 1210 and rotatably supports the guide support 1230.

The guide driver 1220 includes a motor 1221, at least one link assembly 1222, and a guide belt 1223.

The motor 1221 is installed on the other side of the mounting frame 1100 and generates a rotational driving force. The motor 1221 is operatively connected to the guide belt 1223 and transmits the rotational driving force to the guide belt 1223.

The motor 1221 includes a motor pulley 1221a and a motor support member 1221b.

The guide belt 1223 is wound around the motor pulley 1221a.

The motor support member 1221b is installed on the second support frame 1120 and rotatably supports the motor 1221 and the motor pulley 1221a. One side surface of the motor support member 1221b is inwardly recessed, and the motor support member 1221b guides a part of the guide belt 1223 wound around the motor pulley 1221a. For example, a part of the guide belt 1223 can move within the one side surface of the motor support member 1221b.

The motor 1221 can be connected to a power generator, such as an external power supply or a built-in battery and supplied with power. The motor 1221 generates a rotational driving force and transmits the rotational driving force to the motor pulley 1221a.

When the motor 1221 is supplied with power from the power generator, the motor 1221 generates a rotational driving force. Further, when a plurality of sensors 1250 senses a rotation link 1222ba, the generation of the rotational driving force by the motor 1221 can be stopped in response to signals transmitted from at least one sensor 1250 to the power generator. This will be described in more detail along with the sensor 1250.

The link assembly 1222 is rotatably installed on the guide body 1210 and supports the guide support 1230 and the opening and closing plate 1240. A plurality of link assemblies 1222 is provided and installed on the plurality of guide bodies 1210, respectively. The link assemblies 1222 are provided on opposites sides of the mounting frame 1100.

One of the link assemblies 1222 (a link assembly located on the left of the drawing) receives the rotational driving force generated by the motor 1221 through the guide belt 1223. Then, the one link assembly 1222 tilts (rotates) the guide support 1230 and the opening and closing plate 1240. The other link assembly 1222 can assist in stably supporting the guide support 1230 and the opening and closing plate 1240 as they tilt (rotate).

The link assembly 1222 includes a link pulley 1222a, a first link 1222b, a second link 1222c, and a third link 1222d.

The link pulley 1222a is rotatably coupled to the guide body 1210 and the first support frame 1110, and the guide belt 1223 is wound around the link pulley 1222a. The link pulley 1222a is coaxially coupled to one side of the rotation link 1222ba (and the other side of a connection link 1222bb).

The first link 1222b tilts the guide support 1230 by means of the rotational driving force transmitted from the guide belt 1223.

The first link 1222b includes the rotation link 1222ba, the connection link 1222bb, and a support link 1222bc.

One side of the rotation link 1222ba is rotatably installed on the guide body 1210 and coaxially coupled to the link pulley 1222a. The rotation link 1222ba is tilted between a first position and a second position, and its rotation range is restricted by the plurality of sensors 1250.

The first position refers to a disposition angle at which the display panel assembly 1500 is horizontally disposed in the roof panel 10. Further, the second position refers to a disposition angle at which a part of the display panel assembly 1500 is extended below the mounting frame 1100. Specifically, the first position and the second position are disposed along a circumferential direction of a circle centering on the one side of the rotation link 1222ba (or the intersection direction) as a center axis. The second position is disposed higher than the first position.

A tilting angle of the rotation link 1222ba can be restricted by one of a first sensor 1251 and a second sensor 1252, which will be described later.

One side of the connection link 1222bb is coupled to one side of the rotation link 1222ba and the link pulley 1222a and the other side thereof is fixed to the support link 1222bc. The connection link 1222bb transmits, to the support link 1222bc, the rotational driving force the guide belt 1223 which has been transmitted through the rotation link 1222ba.

The connection link 1222bb is tilted with respect to the rotation link 1222ba. The connection link 1222bb is disposed at an obtuse angle with respect to the rotation link 1222ba.

Further, one side of the third link 1222d is rotatably coupled to a central portion of the connection link 1222bb. While the connection link 1222bb is tilted, the third link 1222d is applied with pressure by the connection link 1222bb. For example, tilting of the connection link 1222bb imparts a rotational force to an end of the third link 1222d.

The support link 1222bc supports the guide support 1230. One side of the support link 1222bc is fixed to the connection link 1222bb and the other side thereof is fixed to a movable block 1231c of the guide support 1230. While the connection link 1222bb is tilted, the support link 1222bc tilts the guide support 1230. Further, while the guide support 1230 is tilted, the display panel assembly 1500 supported on the guide support 1230 is bent. The support link 1222bc has a plate shape extending in the intersection direction.

The second link 1222c is installed on the opening and closing plate 1240 and applies pressure to the opening and closing plate 1240 in conjunction with the first link 1222b and the third link 1222d. While the second link 1222c is disposed vertically with respect to (e.g., normal to) the opening and closing plate 1240, one side of the second link 1222c is coupled to the opening and closing plate 1240. The other side of the second link 1222c is rotatably coupled to the third link 1222d.

The third link 1222d connects the first link 1222b and the second link 1222c. With the one side of the connection link 1222bb and the support protrusions 1211 as a rotation stage, the first link 1222b, the second link 1222c, and the third link 1222d constitute a pivotable four-bar link structure. Further, the first link 1222b, the second link 1222c, and the third link 1222d are rotated relative to each other to tilt (rotate) the guide support 1230 and the opening and closing plate 1240.

The guide belt 1223 is disposed inside the first support frame 1110 in the intersection direction and transmits the rotational driving force generated by the motor 1221 to the link assembly 1222. One side of the guide belt 1223 is wound around the motor pulley 1221a and the other side thereof is wound around the link pulley 1222a of the link assembly 1222. Thus, the guide belt 1223 can be located between the first support frame 1110 and the motor support 1221b.

The guide support 1230 is connected to the display panel assembly 1500 and tilted with respect to the mounting frame 1100. An end of the guide support 1230 is coupled to an end of the display panel assembly 1500. The guide support 1230 is applied with pressure by the display panel assembly 1500 which is moved along the one direction by the panel transfer unit 1400. As the guide support 1230 increases in length, as described below, the guide support 1230 guides sliding of the display panel assembly 1500.

The guide support 1230 has a telescopic structure which can be increased in length. The increased length of the guide support 1230 can be three times to four times greater than the length of the first support frame 1110 along the vertical direction (i.e., the height of the mounting frame 1100). While the increased length of the guide support 1230 is described as being up to three times to four times greater than the length of the first support frame 1110 along the vertical direction, it is not so limited. However, an excessive stress could be generated in the guide support 1230 by a load of the extended guide support 1230 if it is increased too much, which could result in a decrease in durability of the guide support 1230.

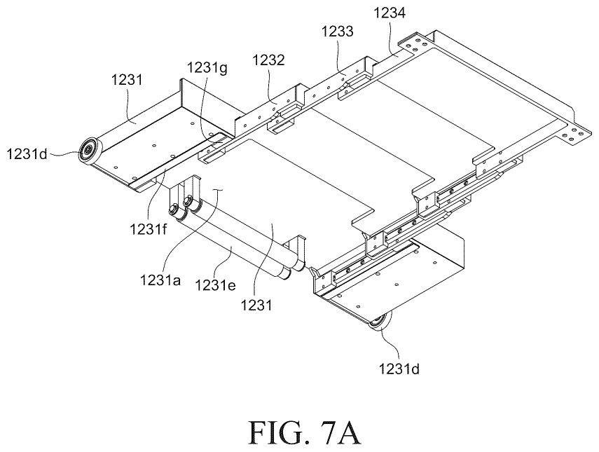

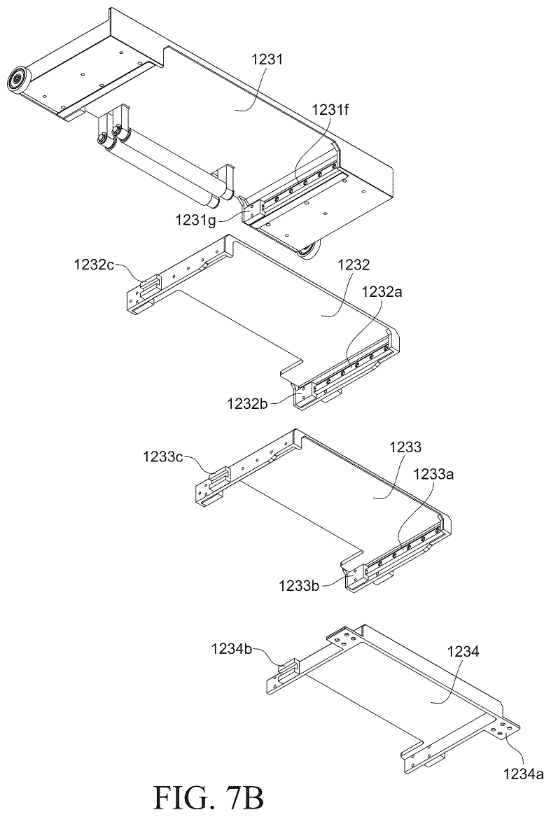

FIG. 7A is a bottom perspective view of a guide support which is deployed according to an embodiment of the present disclosure. FIG. 7B is an exploded perspective view of the guide support according to an embodiment of the present disclosure.

Referring to FIG. 1A through FIG. 7B, the guide support 1230 includes a main guide plate 1231, a plurality of sub-guide plates 1232 and 1233, and a connection guide plate 1234.

The main guide plate 1231 is coupled to the support link 1222bc. Both sides of the main guide plate 1231 are supported by a plurality of support links 1222bc of the guide driver 1220.

An accommodation groove 1231a is inwardly recessed at an end on one side of the main guide plate 1231. In the accommodation groove 1231a of the main guide plate 1231, the plurality of sub-guide plates 1232 and 1233 is accommodated to be deployed in a parallel direction with respect to the main guide plate 1231.

The main guide plate 1231 includes at least one movable rail 1231b, the movable block 1231c, at least one guide roller 1231d, at least one guide support roller 1231e, at least one auxiliary movable rail 1231f, and at least one auxiliary movable block 1231g.

A plurality of movable rails 1231b is provided and installed at both upper ends, respectively, of the main guide plate 1231. The movable rail 1231b extends parallel with respect to the main guide plate 1231. The movable rail 1231b serves as a path for sliding the movable block 1231c.

A plurality of movable blocks 1231c is provided and relatively movably coupled to the plurality of movable rails 1231b, respectively, in a sliding manner.

While the movable rail 1231b is fixed, the movable block 1231c can move forwards or backwards on the movable rail 1231b. Meanwhile, while the movable block 1231c is fixed, the movable rail 1231b can move forwards or backwards.

Further, the support link 1222bc is fixed onto the movable block 1231c.

Before the guide support 1230 is tilted (i.e., while the guide support 1230 is horizontally disposed), the movable block 1231c is disposed on the other side of the movable rail 1231b as shown in FIG. 4A. Further, while the guide support 1230 is tilted, the movable block 1231c is disposed adjacent to one side of the movable rail 1231b as shown in FIG. 4B.

When the guide driver 1220 operates to tilt the guide support 1230, the movable rail 1231b relatively movably coupled to the movable block 1231c is pushed in conjunction with tilting (rotation) of the link assembly 1222. Since the movable rail 1231b relatively movably coupled to the movable block 1231c is pushed in conjunction with tilting (rotation) of the link assembly 1222, the movable rail 1231b is tilted together with the guide support 1230 while maintaining the same radius based on a bending portion of the display panel assembly 1500.

A plurality of guide rollers 1231d is provided and rotatably installed at both ends on the other side of the main guide plate 1231. The guide roller 1231d is rotatably mounted on the first support frame 1110. For example, the guide roller 1231d can be mounted on the rounded surface of the first support frame 1110. When the guide support 1230 is tilted, the guide roller 1231d moves along the rounded surface of the first support frame 1110 and supports the main guide plate 1231 to stably tilt the main guide plate 1231.

A plurality of guide support rollers 1231e is provided and protrudes from a central portion on the other side of the main guide plate 1231 to be located below the main guide plate 1231. Further, the plurality of guide support rollers 1231e comes into rotational contact with an upper portion of the display panel assembly 1500. When the guide support 1230 is tilted, the plurality of guide support rollers 1231e is disposed to face a second lower roller 1322, which will be described later. While the guide support 1230 is tilted, each of upper and lower sides of the bending portion of the display panel assembly 1500 is supported by the plurality of guide support rollers 1231e and a plurality of second lower rollers 1322. Thus, the display panel assembly 1500 can stably slide. Therefore, it is possible to suppress damage to the display panel assembly 1500 while the display panel assembly 1500 slides.

A plurality of auxiliary movable rails 1231f is provided and installed on both inner surfaces of the main guide plate 1231, which form the accommodation groove 1231a. The auxiliary movable rail 1231f extends parallel with respect to the main guide plate 1231. The auxiliary movable rail 1231f serves as a path for sliding the auxiliary movable block 1231g.

A plurality of auxiliary movable blocks 1231g is provided and slidably coupled to the plurality of auxiliary movable rails 1231f, respectively. The auxiliary movable block 1231g can be pushed or pulled parallel with respect to the main guide plate 1231 and moved on the auxiliary movable rail 1231f in conjunction with sliding of the display panel assembly 1500. A sub-guide plate (i.e., a first sub-guide plate 1232) is coupled to the auxiliary movable block 1231g. While the auxiliary movable block 1231g moves forwards and backwards along the auxiliary movable rail 1231f, the sub-guide plate (i.e., the first sub-guide plate 1232) can be moved forwards (i.e., deployed) or moved backwards (i.e., accommodated).

A plurality of sub-guide plates 1232 and 1233 is installed in the accommodation groove 1231a of the main guide plate 1231. The plurality of sub-guide plates 1232 and 1233 can be deployed parallel with respect to the main guide plate 1231. The plurality of sub-guide plates 1232 and 1233 includes driving rails 1232a and 1233a and driving blocks 1232b and 1233b, respectively, and overlaps each other to be deployed in a telescopic structure.

In an embodiment of the present disclosure, the number of the plurality of sub-guide plates 1232 and 1233 is two as shown in FIG. 7A and FIG. 7B. Further, the two sub-guide plates 1232 and 1233 include the first sub-guide plate 1232 and a second sub-guide plate 1233. Further, the driving rails for the two sub-guide plates 1232 and 1233 include a first driving rail 1232a and a second driving rail 1233a. Furthermore, the driving blocks for the two sub-guide plates 1232 and 1233 include a first driving block 1232b and a second driving block 1233b.

The first sub-guide plate 1232 is a sub-guide plate having a greater size among the plurality of sub-guide plates 1232 and 1233. The inside of the first sub-guide plate 1232 is hollowed (e.g., recessed) along a direction along which the main guide plate 1231 extends. The second sub-guide plate 1233 is accommodated in the hollow portion of the first sub-guide plate 1232.

The first driving rail 1232a and the first driving block 1232b are installed in the hollow inside of the first sub-guide plate 1232.

The first driving rail 1232a is installed on an inner surface of the first sub-guide plate 1232. The first driving rail 1232a extends parallel with respect to the first sub-guide plate 1232. The first driving block 1232b is slidably coupled to the first driving rail 1232a.

The first driving block 1232b is slidably coupled to the first driving rail 1232a. The first driving block 1232b can be pushed or pulled parallel with respect to the first sub-guide plate 1232 and moved on the first driving rail 1232a in conjunction with sliding of the display panel assembly 1500.

The second sub-guide plate 1233 is fixed to the first driving block 1232b. Further, the second sub-guide plate 1233 can be accommodated in the first sub-guide plate 1232 or deployed to the outside of the first sub-guide plate 1232 in conjunction with forward and backward movements of the first driving block 1232b.

The first driving rail 1232a and the first driving block 1232b can be configured as linear motion guides.

Further, a first guide block 1232c is installed on an outer side surface of the first sub-guide plate 1232.

The first guide block 1232c engages with the movable rail 1231b at a position where the first guide block 1232c does not interfere with the movable block 1231c. The first guide block 1232c includes a slit inwardly recessed in one surface facing the movable rail 1231b. The first guide block 1232c is slidably coupled to the movable rail 1231b through the slit. The first sub-guide plate 1232 can be stably deployed from the main guide plate 1231 or accommodated into the main guide plate 1231 by the first guide block 1232c.

The second sub-guide plate 1233 is a sub-guide plate having a smaller size among the plurality of sub-guide plates 1232 and 1233. The second sub-guide plate 1233 has a size suitable to be inserted into the hollow inside of the first sub-guide plate 1232. The inside of the second sub-guide plate 1233 is hollowed along a direction along which the first sub-guide plate 1232 extends. The connection guide plate 1234 is accommodated in the hollow portion of the second sub-guide plate 1233.

The second driving rail 1233a and the second driving block 1233b are installed in the hollow inside of the second sub-guide plate 1233.

The second driving rail 1233a is installed on an inner surface of the second sub-guide plate 1233. The second driving rail 1233a extends parallel with respect to the second sub-guide plate 1233. The second driving block 1233b is slidably coupled to the second driving rail 1233a.

The second driving block 1233b is slidably coupled to the second driving rail 1233a. The second driving block 1233b can be pushed or pulled parallel with respect to the second sub-guide plate 1233 and moved on the second driving rail 1233a in conjunction with sliding of the display panel assembly 1500.

The connection guide plate 1234 is fixed to the second driving block 1233b. Further, the connection guide plate 1234 can be accommodated in the second sub-guide plate 1233 or deployed to the outside of the second sub-guide plate 1233 in conjunction with forward and backward movements of the second driving block 1233b.

The second driving rail 1233a and the second driving block 1233b can be configured as linear motion guides.

Further, a second guide block 1233c is installed on an outer side surface of the second sub-guide plate 1233.

The second guide block 1233c engages with the first driving rail 1232a at a position where the second guide block 1233c does not interfere with the first driving block 1232b. The second guide block 1233c includes a slit inwardly recessed in one surface facing the first driving rail 1232a. The second guide block 1233c is slidably inserted into the first driving rail 1232a through the slit. The second sub-guide plate 1233 can be stably deployed from the first sub-guide plate 1232 or accommodated into the first sub-guide plate 1232 by the second guide block 1233c.

The connection guide plate 1234 supports an end of the display panel assembly 1500. The connection guide plate 1234 has a size suitable to be inserted into the hollow inside of the second sub-guide plate 1233 and is slidably installed in the hollow inside of the second sub-guide plate 1233. The connection guide plate 1234 is fixed to the second driving block 1233b. Further, the connection guide plate 1234 can be accommodated in the second sub-guide plate 1233 or deployed to the outside of the second sub-guide plate 1233 in conjunction with forward and backward movements of the second driving block 1233b.

Further, a fixing piece 1234a for fixing the display panel assembly 1500 is provided on the connection guide plate 1234. The fixing piece 1234a can be fixed to the display panel assembly 1500 by a bolt and a nut.

Further, a third guide block 1234b is installed on an outer side surface of the connection guide plate 1234.

The third guide block 1234b engages with the second driving rail 1233a at a position where the third guide block 1234b does not interfere with the second driving block 1233b. The third guide block 1234b includes a slit inwardly recessed in one surface facing the second driving rail 1233a. The third guide block 1234b is slidably inserted into the second driving rail 1233a through the slit. The connection guide plate 1234 can be stably deployed from the second sub-guide plate 1233 or accommodated into the second sub-guide plate 1233 by the third guide block 1234b.

The opening and closing plate 1240 is coupled rotatably to one side of the guide body 1210 and connected to the guide driver 1220. Further, the opening and closing plate 1240 is rotated (tilted) in conjunction with rotation of the guide support 1230 by the guide driver 1220.

The opening and closing plate 1240 closes the opening 11 of the roof panel 10 while the guide support 1230 and the display panel assembly 1500 are accommodated on the roof panel 10. Further, the opening and closing plate 1240 opens the opening 11 of the roof panel 10 to deploy the guide support 1230 and the display panel assembly 1500 to below the roof panel 10.

The opening and closing plate 1240 extends along the intersection direction and has a size equal to or smaller than the opening 11 of the roof panel 10.

A groove in which the insertion protrusions 1212 of the guide body 1210 are inserted is formed on one side of the opening and closing plate 1240. The insertion protrusions 1212 are inserted into the opening and closing plate 1240, and the opening and closing plate 1240 is rotatably supported by the guide support 1230. When the guide driver 1220 does not operate, the opening and closing plate 1240 is disposed parallel with respect to the roof panel 10, and the opening 11 of the roof panel 10 is closed. Further, the roof panel 10 has an overall flat surface. Thus, the aesthetics of the interior of the vehicle can be improved.

The second link 1222c of the guide driver 1220 is fixed to an upper surface of the opening and closing plate 1240. While the guide driver 1220 tilts the guide support 1230, the opening and closing plate 1240 connected to the guide driver 1220 through the second link 1222c is also tilted. When the opening and closing plate 1240 is tilted, the opening 11 of the roof panel 10 is opened and a path for deploying the guide support 1230 and the display panel assembly 1500 to extend below the roof panel 10 is formed.

The sensor 1250 is installed on the guide body 1210 and senses the first link 1222b. The first sensor 1251 and the second sensor 1252 of the sensor 1250, which are disposed at different positions from each other, sense the rotation link 1222ba which moves along a circumferential direction of a circle centering on the one side of the rotation link 1222ba. When the sensor 1250 is disposed to face the other side of the rotation link 1222ba being rotated, the sensor 1250 transmits a signal to the power generator. The rotation of the rotation link 1222ba is stopped by the power generator.

The sensor 1250 includes the first sensor 1251 and the second sensor 1252.

The first sensor 1251 is disposed on a rotation path of the rotation link 1222ba. The first sensor 1251 is disposed on a movement path of the other side of the rotation link 1222ba revolving along the circumferential direction. When the first sensor 1251 senses the rotation link 1222ba, the first sensor 1251 transmits a sensing signal to the power generator. When the power generator receives the sensing signal from the first sensor 1251, the power generator stops the supply of power to the motor 1221.

The second sensor 1252 is disposed on a rotation path of the rotation link 1222ba. The second sensor 1252 is disposed higher than the first sensor 1251 on the movement path of the other side of the rotation link 1222ba revolving along the circumferential direction. When the second sensor 1252 senses the rotation link 1222ba, the second sensor 1252 transmits a sensing signal to the power generator. When the power generator receives the sensing signal from the second sensor 1252, the power generator stops the supply of power to the motor 1221.

The driving of the motor 1221 is stopped in response to the signals received by the first sensor 1251 and the second sensor 1252. The first sensor 1251 and the second sensor 1252 can determine whether to drive the motor 1221 and restrict the degree of tilting (e.g., a tilting angle) of the guide support 1230, the opening and closing plate 1240, and the display panel assembly 1500.

Meanwhile, in a range in which the rotation link 1222ba is not sensed by the first sensor 1251 and the second sensor 1252, the motor 1221 can be driven freely. Further, the degree of tilting (e.g., the tilting angle) of the guide support 1230, the opening and closing plate 1240, and the display panel assembly 1500 can vary.

The roller unit 1300 supports sliding of the display panel assembly 1500.

The roller unit 1300 includes at least one upper roller 1310 and at least one lower roller 1320.

A plurality of upper rollers 1310 is provided and disposed in an upper area at a relative high position in the first support frame 1110. The plurality of upper rollers 1310 is spaced apart from each other along the one direction. The plurality of upper rollers 1310 on the display panel assembly 1500 rotatably supports the display panel assembly 1500.

A plurality of lower rollers 1320 is provided and disposed in a lower area at a lower position than the plurality of upper rollers 1310 in the first support frame 1110. The plurality of lower rollers 1320 under the display panel assembly 1500 rotatably supports the display panel assembly 1500.

The lower rollers 1320 include at least one first lower roller 1321 and at least one second lower roller 1322.

The first lower roller 1321 is disposed to face the plurality of upper rollers 1310. The first lower roller 1321 rotatably supports a flat portion of the display panel assembly 1500 which is not bent.

The second lower roller 1322 is disposed in a downwardly tilting direction with respect to a plurality of first lower rollers 1321. The second lower roller 1322 can be tilted at an angle of 90° to 130°, such as 110°, with respect to a plurality of first lower rollers 1321. The second lower roller 1322 together with the guide support roller 1231e rotatably supports the display assembly 1500. The second lower roller 1322 under the display panel assembly 1500, which is bent, rotatably supports the display panel assembly 1500. Further, the guide support roller 1231e on the display panel assembly 1500, which is bent, rotatably supports the display panel assembly 1500.

Each of the plurality of upper rollers 1310 and the plurality of lower rollers 1320 is configured as an idle roller. Each idle roller may have a cylindrical or spherical shape.

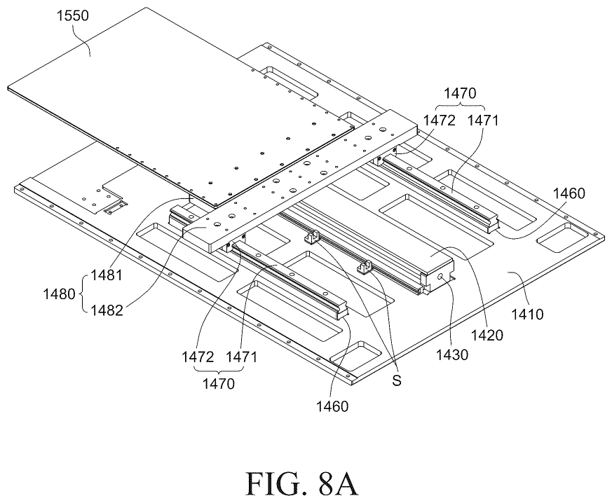

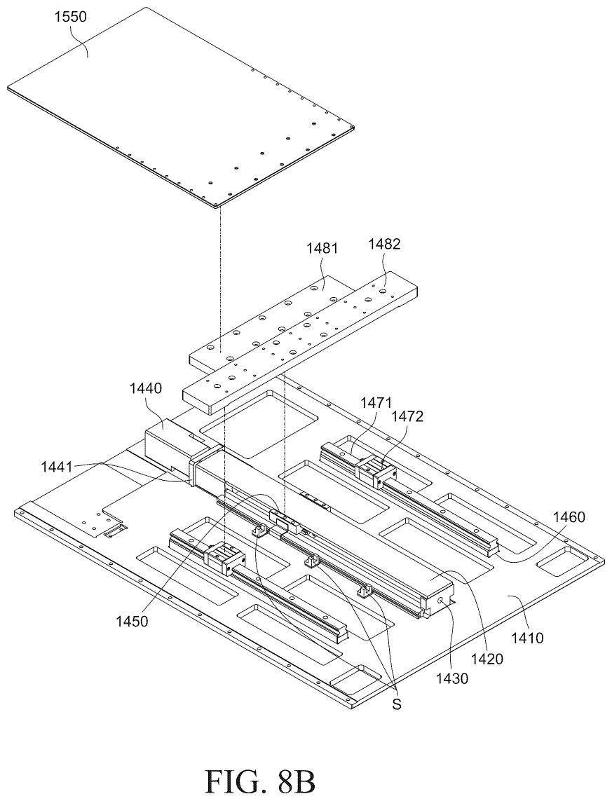

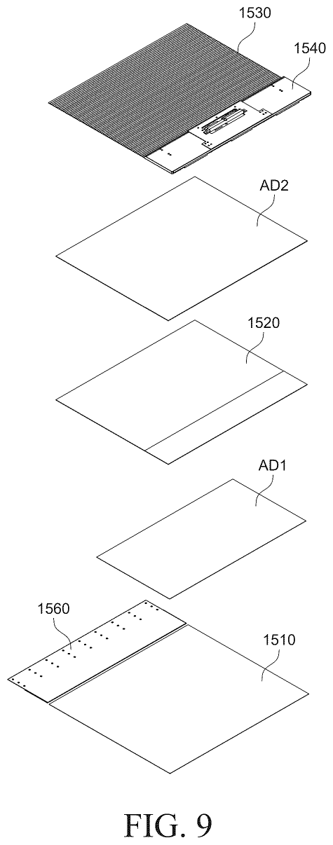

FIG. 8A is a perspective view illustrating a structure of a panel transfer unit according to an embodiment of the present disclosure. FIG. 8B is an exploded perspective view illustrating the structure of the panel transfer unit according to an embodiment of the present disclosure. FIG. 9 is an exploded perspective view of a display panel assembly according to an embodiment of the present disclosure.

Referring to FIG. 1A through FIG. 9, the panel transfer unit 1400 is mounted on the mounting frame 1100 and serves to slide the display panel assembly 1500.

The panel transfer unit 1400 includes a coupling plate 1410, at least one support block 1420, a rotary shaft 1430, a driving motor 1440, a carrier 1450, a pair of supports 1460, at least one linear motion (LM) guide 1470, and a transfer bridge 1480.

The coupling plate 1410 is mounted on the second support frame 1120 and fixed to the plurality of first support frames 1110. The support block 1420, a driving motor support member 1441, and the pair of supports 1460 can be fixed onto the coupling plate 1410.

The support block 1420 can be more than one. Each support block 1420 can be fixed onto the coupling plate 1410. The support block 1420 can be spaced apart from each other along a sliding direction of the display panel assembly 1500.

A bearing is provided inside the support block 1420. A first end and a second end of the rotary shaft 1430 are rotatably installed on the bearing provided inside the support block 1420. A pair of bearings serve to fix the rotary shaft 1430 at a predetermined position so as not to be eccentric. That is the pair of bearings may be colinear. The pair of bearings support a weight of the rotary shaft 1430 as it rotates and a load applied to the rotary shaft 1430.

The rotary shaft 1430 can move the carrier 1450 in the sliding direction of the display panel assembly 1500 by means of the rotational driving force transmitted by the driving motor 1440.

The rotary shaft 1430 can be configured as a ball screw. The rotary shaft 1430 serves to convert a rotational motion of the driving motor 1440 into a linear reciprocating motion of the carrier 1450 disposed on the rotary shaft 1430. The rotary shaft 1430 is rotated by the driving motor 1440 and serves to linearly move the carrier 1450 toward one side or the other side of the support block 1420. That is, the rotary shaft 1430 can be rotated by the drive motor 1440 and rectilinearly move the carrier 1450 between one end of the support blocks 1420 and the other end of the support blocks 1420. Alternatively, other devices that convert rotary motion to linear motion, such as, a rack and pinion, could be used.

The driving motor 1440 is connected to the support block 1420 and serves to transmit a driving force to the rotary shaft 1430.

The driving motor 1440 is connected to the rotary shaft 1430 through a coupler. The coupler holds the rotary shaft 1430 during movement of the carrier 1450 even when the concentricity (co-axis) of the rotary shaft 1430 is deviated and rotates the rotary shaft 1430 in a predetermined axial direction.

The driving motor 1440 connected to the other side of the support block 1420 is supported by the driving motor support member 1441 disposed between the driving motor 1440 and the coupler. The driving motor support member 1441 is fixed onto the coupling plate 1410.

The driving motor 1440 can be connected to a power generator, such as an external power supply or a built-in battery and supplied with power. The driving motor 1440 generates a rotational driving force and transmits the rotational driving force to the rotary shaft 1430 configured as a ball screw.

The driving motor 1440 can rotate the rotary shaft 1430 depending on a position of a first LM block 1472 received by the power generator from a position sensor S.

The carrier 1450 is disposed on the rotary shaft 1430 and can linearly move in the sliding direction of the display panel assembly 1500 by means of the rotational driving force transmitted by the driving motor 1440.

The pair of supports 1460 are disposed on opposite sides of the support block 1420. The pair of supports 1460 are fixed onto the coupling plate 1410 along a movement direction of the carrier 1450.

A plurality of position sensors S is provided and spaced apart from and parallel to each other along the one direction on one side of the support block 1420. The plurality of position sensors S senses a position of the first LM block 1472 which moves together with the carrier 1450. The plurality of position sensors S transmits the sensed position signal of the first LM block 1472 to the power generator.

The plurality of position sensors S serves as limit sensors to restrict movement of the carrier 1450 by sensing the position of the first LM block 1472. Since the movement of the carrier 1450 is restricted by the plurality of position sensors S, it is possible to suppress damage or breakage of the panel transfer unit 1400 or the generation of noise.

The power generator can control (turn on or off) driving of the driving motor 1440 in response to the received position signal of the first LM block 1472. The power generator can control the driving motor 1440 to rotate the rotary shaft 1430 in response to the received position signal of the first LM block 1472. For example, the drive motor 1440 can be turned off when the first LM block 1472 reaches a predetermined position next to one of the position sensors S.

The LM guide 1470 supports sliding of the display panel assembly 1500.

The LM guide 1470 includes a pair of first guide rails 1471 and a pair of first LM blocks 1472.

The pair of first guide rails 1471 are fixed onto the pair of supports 1460, respectively. The first guide rail 1471 serves as a path for moving the first LM block 1472.

The pair of first LM blocks 1472 are movably coupled to the pair of first guide rails 1471, respectively. A second transfer member 1482 is coupled onto the pair of first LM blocks 1472. The pair of first LM blocks 1472 are coupled to the second transfer member 1482 and connected to the carrier 1450 through a first transfer member 1481 integrally formed with the second transfer member 1482 (see FIG. 8A and FIG. 8B). Therefore, the pair of first LM blocks 1472 operate in conjunction with movement of the carrier 1450. For example, when the carrier 1450 reciprocates forwards and backwards along the one direction, the pair of first LM blocks 1472 connected to the carrier 1450 through the first transfer member 1481 and the second transfer member 1482 also reciprocate forwards and backwards in the one direction along the pair of first guide rails 1471 together with the carrier 1450.

The transfer bridge 1480 is coupled onto the carrier 1450 and the first LM block 1472. The transfer bridge 1480 moves the display panel assembly 1500 forwards and backwards.

The transfer bridge 1480 includes the first transfer member 1481 and the second transfer member 1482.

The first transfer member 1481 is coupled onto the carrier 1450. An interface board 1550 of the display panel assembly 1500 is coupled onto the first transfer member 1481. Therefore, the interface board 1550 of the display panel assembly 1500 as well as the pair of first LM blocks 1472 can slide by reciprocation of the carrier 1450.

The second transfer member 1482 is formed integrally with the first transfer member 1481 and coupled onto the pair of first LM blocks 1472. The second transfer member 1482 has a greater length than the first transfer member 1481 along the intersection direction, and has a greater thickness than the first transfer member 1481 in the vertical direction. A predetermined step is formed between the second transfer member 1482 and the first transfer member 1481. The interface board 1550 is mounted at a step portion on the first transfer member 1481 having a smaller thickness than the second transfer member 1482.

A connection panel 1560 of the display panel assembly 1500 is mounted on the second transfer member 1482 and can move together with the carrier 1450 in conjunction with movement of the carrier 1450. Therefore, when the carrier 1450 reciprocates forwards and backwards along the one direction, the pair of first LM blocks 1472 also reciprocate. Further, the second transfer member 1482 coupled onto the pair of first LM blocks 1472 and the connection panel 1560 reciprocate forwards and backwards along the one direction. When the connection panel 1560 reciprocates forwards and backwards along the one direction, a display panel 1510 of the display panel assembly 1500 also moves.

The interface board 1550 of the display panel assembly 1500 is coupled onto the first transfer member 1481. By movement of the carrier 1450 at the same time as movement of the display panel 1510, the interface board 1550 slides together with the display panel 1510.

The display panel assembly 1500 is slidably mounted on the mounting frame 1100.

Referring to FIG. 1A through FIG. 9, the display panel assembly 1500 includes the display panel 1510, a mid-cover 1520, a plurality of back bars 1530, a support panel 1540, the interface board 1550, and the connection panel 1560.

The display panel 1510 can slide to below the roof panel 10 (i.e., the inside of the vehicle) through the opening 11. The connection panel 1560 is coupled to one side of the display panel 1510 and connected to the second transfer member 1482 by the connection panel 1560. When the carrier 1450 moves, the display panel 1510 can slide by means of a driving force transmitted through the first transfer member 1481 and the second transfer member 1482.

The display panel 1510 includes a display element to display images, a driving element to drive the display element, and wiring lines to transmit various signals to the display element and the driving element. The display panel 1510 is usually disposed parallel with respect to the coupling plate 1410, but a portion of the display panel 1510 can be bent by driving of the guide driver 1220. While the display panel 1510 is bent, the display panel 1510 can be deployed to be tilted toward below the roof panel 10 through the opening 11 opened by tilting of the opening and closing plate 1240.

The display panel 1510 is bent by the guide driver and the guide support and can be flexible to be slid while being bent.

Further, the display panel 1510 is connected to the interface board 1550 by the connection panel 1560. The display panel 1510 receives an electrical signal from the interface board 1550 through the connection panel 1560.

The mid-cover 1520 is disposed on one surface of the display panel 1510 and supports the display panel 1510. The mid-cover 1520 can have a greater size than the display panel 1510 to protect the display panel 1510 from external impacts.

The mid-cover 1520 contains a malleable material so that plastic deformation does not occur in the mid-cover 1520 even when the display panel assembly 1500 is repeatedly slid. More specifically, the display panel 1510 can be bent by the guide member 1200, and the mid-cover 1520 can contain a material having a yield stress equal to or greater than a stress applied to the mid-cover 1520 while the display panel 1510 is bent and slid. For example, the mid-cover 1520 can contain a material such as metal, rubber, plastic, or fabric. However, the material of the mid-cover 1520 is not limited thereto and can be variously modified depending on the design as long as it can satisfy property requirements, such as the amount of thermal deformation, radius of curvature, or rigidity.

The mid-cover 1520 can have a small thickness so that deformation does not occur in the mid-cover 1520 even when the display panel assembly 1500 is repeatedly slid.

A first adhesive layer AD1 is disposed between the mid-cover 1520 and the display panel 1510.

The first adhesive layer AD1 serves to bond the mid-cover 1520 to the display panel 1510. The first adhesive layer AD1 is made of an adhesive material and contains a thermally curable or naturally curable adhesive. The first adhesive layer AD1 can contain an optical clear adhesive (OCA), a pressure sensitive adhesive (PSA), etc., but is not limited thereto.

The plurality of back bars 1530 is disposed on one surface of the mid-cover 1520.

The plurality of back bars 1530 supports the display panel 1510 and the mid-cover 1520. The plurality of back bars 1530 can have a greater thickness than the mid-cover 1520 and protects the display panel 1510 and the mid-cover 1520 from external impacts.

The plurality of back bars 1530 contains a rigid material. The plurality of back bars 1530 can contain a metal material, such as steel use stainless (SUS) and Invar, or a plastic material. However, the material of the plurality of back bars 1530 is not limited thereto and can be variously modified depending on the design as long as it can satisfy property requirements, such as the amount of thermal deformation, radius of curvature, or rigidity.

A second adhesive layer AD2 is disposed between the plurality of back bars 1530 and the mid-cover 1520.

The second adhesive layer AD2 serves to bond the mid-cover 1520 to the plurality of back bars 1530. The second adhesive layer AD2 is made of an adhesive material and contains an elastic material. The second adhesive layer AD2 can contain a foam pad and elastic resin but is not limited thereto.

The support panel 1540 is coupled to ends of the plurality of back bars 1530, and the fixing piece 1234a of the connection guide plate 1234 is coupled (e.g., screw-coupled) to an ed of the support panel 1540. The support panel 1540 is supported by the connection guide plate 1234 through the fixing piece 1234a. Further, the mid-cover 1520 and the display panel 1510 are supported by the plurality of back bars 1530 coupled to the support panel 1540. Therefore, when the display panel 1510 is deployed by the panel transfer unit 1400, the connection guide plate 1234 fixed to the support panel 1540 (as well as the plurality of sub-guide plates 1232 and 1233 and the main guide plate 1231) can also be deployed by means of a sliding force of the display panel 1510.

The interface board 1550 is connected to the connection panel 1560. The interface board 1550 is electrically connected to the display panel 1510 through the connection panel 1560. The interface board 1550 can transmit and receive data, signals, or power for displaying images to and from the display panel 1510 through the connection panel 1560. When power is supplied, the interface board 1550 can be connected to an image controller to control images displayed on the display panel 1510 connected through the connection panel 1560.

The interface board 1550 is mounted on the first transfer member 1481 coupled onto the carrier 1450. The interface board 1550 moves forwards and backwards along the one direction in conjunction with movement of the carrier 1450.

The connection panel 1560 serves to electrically connect the interface board 1550 to the display panel 1510. The connection panel 1560 connects the interface board 1550 to the display panel 1510, which enables transmission and receipt of data, signals, or power for displaying images on the display panel 1510. The connection panel 1560 contains a flexible material.

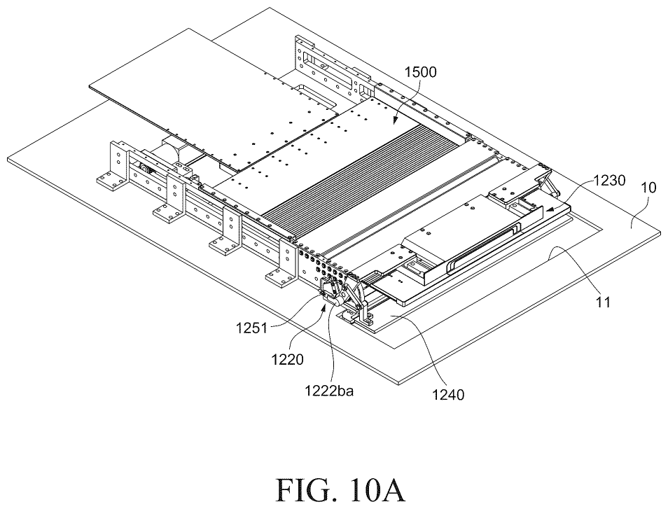

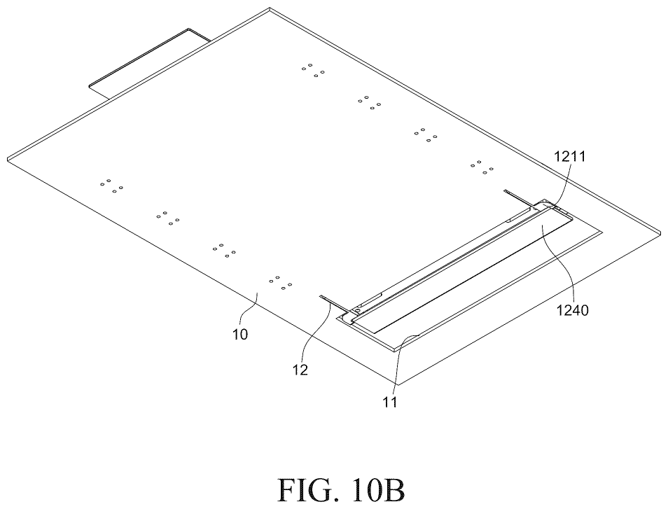

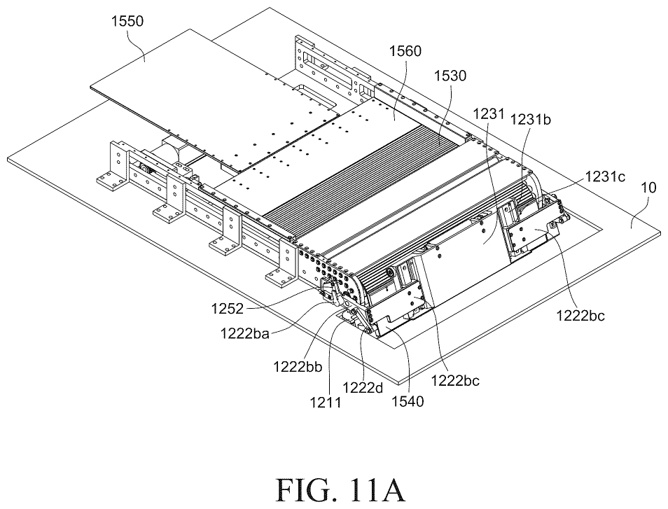

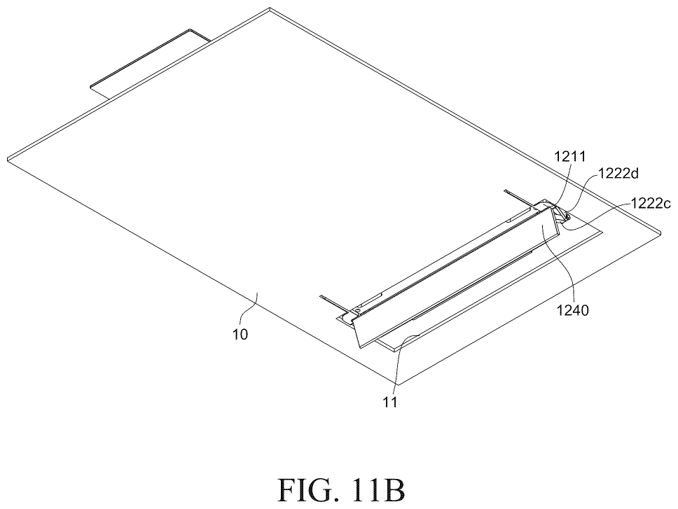

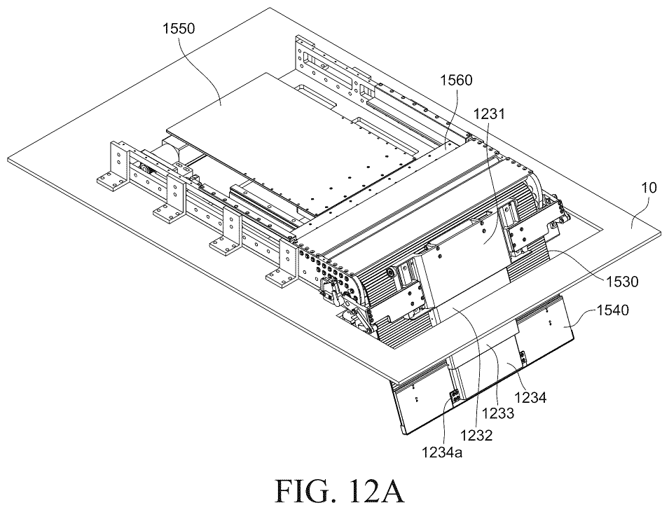

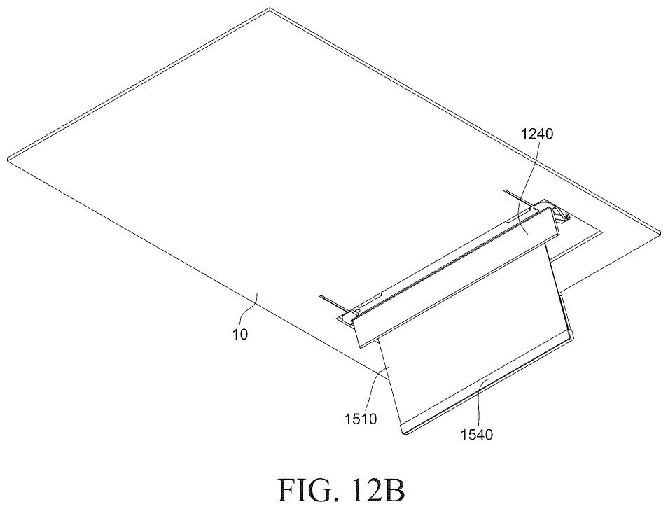

FIG. 10A is a perspective view of the display panel assembly which is accommodated according to an embodiment of the present disclosure. FIG. 10B is a bottom perspective view of the display panel assembly which is accommodated according to an embodiment of the present disclosure. FIG. 11A is a perspective view of the display panel assembly which is bent according to an embodiment of the present disclosure. FIG. 11B is a bottom perspective view of the display panel assembly which is bent according to an embodiment of the present disclosure. FIG. 12A is a perspective view illustrating that a display panel of the display panel assembly is moved and exposed to the outside of a roof panel according to an embodiment of the present disclosure. FIG. 12B is a bottom perspective view illustrating that the display panel of the display panel assembly is moved and exposed to the outside of the roof panel according to an embodiment of the present disclosure.

Hereinafter, a process of deploying the display panel assembly 1500 to the inside of the vehicle through the opening 11 of the roof panel 10 will be described with reference to FIG. 1A through FIG. 12B.

Referring to FIG. 10A and FIG. 10B, the display panel assembly 1500 is accommodated between the roof panel 10 and the outer plate of the vehicle. The display panel assembly 1500 is horizontally disposed along the one direction. In this state, the guide driver 1220 is not driven. Further, the guide support 1230 is disposed along the one direction. Further, the opening 11 of the roof panel 10 is partially covered by the opening and closing plate 1240 disposed horizontally with respect to the roof panel 10. Furthermore, the other side of the rotation link 1222ba of the first link 1222b is disposed to face the first sensor 1251 among the plurality of sensors 1250.

Referring to FIG. 11A and FIG. 11B, the guide driver 1220 is driven, and a part (i.e., a front end) of the display panel assembly 1500 is bent.

The motor 1221 of the guide driver 1220 operates to generate a rotational driving force. The rotational driving force generated by the motor 1221 is transmitted to the guide belt 1223 through the motor pulley 1221a. The rotational driving force transmitted to the guide belt 1223 is transmitted to the first link 1222b, the second link 1222c, and the third link 1222d through the link pulley 1222a.

As shown in FIG. 4B, while one side of the rotation link 1222ba of the first link 1222b is supported by the guide body 1210, the rotation link 1222ba is rotated to a position where the other side of the rotation link 1222ba interacts with the second sensor 1252.

The connection link 1222bb and the support link 1222bc are rotated at the same rotation angle as the rotation link 1222ba in conjunction with rotation of the rotation link 1222ba.

When the connection link 1222bb is rotated, the second link 1222c connected through the third link 1222d is applied with pressure and tilts the opening and closing plate 1240 downwardly. While one side of the opening and closing plate 1240 is supported by the support protrusions 1211 of the guide body 1210, the other side of the opening and closing plate 1240 is applied with pressure by the second link 1222c and tilted downwardly. When the opening and closing plate 1240 is tilted downwardly, the opening 11 is opened to provide a space through which the guide support 1230 is inserted into the opening 11.

Further, when the support link 1222bc is rotated together with the connection link 1222bb, the guide support 1230 is also tilted downwardly. The main guide plate 1231 connected to the support link 1222bc (as well as the plurality of sub-guide plates 1232 and 1233 and the connection guide plate 1234) is tilted downwardly and inserted into the opening 11. In the process of tilting the main guide plate 1231, the display panel assembly 1500 of which an end is supported by the connection guide plate 1234 is bent downwardly.

Further, in the process of tilting the guide support 1230, the movable rail 1231b relatively movably coupled to the movable block 1231c of the main guide plate 1231 is pushed in conjunction with tilting (rotation) of the connection link 1222bb and the support link 1222bc. This is to bend the display panel assembly 1500 downwardly with a continuous length. By comparison between FIG. 4A and FIG. 4B, the support link 1222bc is located at an end on the other side of the main guide plate 1231 before the guide support 1230 is tilted. Further, the support link 1222bc is located adjacent to one side of the main guide plate 1231 after the guide support 1230 is tilted.

Furthermore, in the process of tilting the guide support 1230, an end of the bent display panel assembly 1500 is mounted on the second lower roller 1322. An upper surface of the display panel assembly 1500 mounted on the second lower roller 1322 comes into contact with the guide support roller 1231e.

Moreover, in the process of tilting the guide support 1230, the end of the bent display panel assembly 1500 is disposed in parallel to the tilted opening and closing plate 1240.

Referring to FIG. 12A and FIG. 12B, when the panel transfer unit 1400 operates, the display panel assembly 1500 is guided by the tilted guide member 1200 and deployed to below the roof panel 10 (i.e., the inside of the vehicle).

When the driving motor 1440 of the panel transfer unit 1400 operates, a rotational driving force is generated. The rotational driving force generated by the driving motor 1440 is transmitted to the carrier 1450 through the rotary shaft 1430. The carrier 1450 slides and moves forwards in the one direction along the support block 1420.

When the carrier 1450 moves forwards, the carrier 1450 pushes the transfer bridge 1480 along the one direction. The first LM block 1472 connected through the first transfer member 1481 and the second transfer member 1482 is guided along the first guide rail 1471 and slid in conjunction with forward movement of the carrier 1450.

As shown in FIG. 4C, when the transfer bridge 1480 moves in the one direction in conjunction with movement of the carrier 1450, the connection panel 1560 coupled to the second transfer member 1482 (as well as the mid-cover 1520, the display panel 1510, the back bar 1530, and the support panel 1540) slides forwards. In the process of moving the display panel assembly 1500 forwards, the bent display panel assembly 1500 is slid by the tilted guide support 1230 at a tilting angle of the guide support 1230.

Further, in the process of moving the display panel assembly 1500 forwards, the guide support 1230 is deployed by the support panel 1540 fixed to the connection guide plate 1234. When the support panel 1540 of the display panel assembly 1500 moves forwards in a tilting direction, the connection guide plate 1234 slides in the tilting direction. The connection guide plate 1234 slides in the tilting direction along the second driving rail 1233a, and the second driving block 1233b fixed to the connection guide plate 1234 is disposed at an end of the second driving rail 1233a.

While the second driving block 1233b is disposed at the end of the second driving rail 1233a, the display panel assembly 1500 can move further forwards. In this case, the second driving block 1233b applies pressure to an inner surface of the second sub-guide plate 1233 to deploy the second sub-guide plate 1233 to the outside of the first sub-guide plate 1232. In this way, the first sub-guide plate 1232 is deployed from the inside to the outside of the main guide plate 1231.

The connection guide plate 1234, the first sub-guide plate 1232, and the second sub-guide plate 1233 are deployed in a parallel direction with respect to each other. Therefore, the display panel 1510 of which an end is supported by the connection guide plate 1234 extends in the tilting direction and is disposed as shown in FIG. 4C.

Accordingly, the display panel assembly 1500 can be tilted and guided by the guide member 1200 toward below the roof panel 10 and disposed inside the vehicle.

The embodiments of the present disclosure can also be described as follows:

According to an aspect of the present disclosure, a slidable display device comprises
a mounting frame, a display panel assembly movably coupled to the mounting frame, and a guide member which is tiltably coupled to the mounting frame, supports the display panel assembly, and guides movement of the display panel assembly, wherein the guide member is configured to bend at least a part of the display panel assembly while being tilted.

The guide member can be tilted between a first position and a second position, the display panel assembly can be horizontally disposed while the guide member is disposed at the first position, and at least a part of the display panel assembly can be bent and can be extended below the mounting frame while the guide member is disposed at the second position.

The guide member can include a guide body installed on one side of the mounting frame, a guide support which is connected to the display panel assembly and rotatably tilted with respect to the mounting frame, and a guide driver which is installed on the mounting frame and the guide body and can drive rotatably the guide support.

The guide member can further include an opening and closing plate which is coupled rotatably to one side of the guide body, connected to the guide driver, and can be rotated in conjunction with rotation of the guide support.

The guide driver can include a motor which is installed on the other side of the mounting frame and generates a driving force, a link assembly which connects the guide body to the guide support, and a guide belt which transmits the driving force of the motor to the link assembly.

The link assembly can include a first link which is connected to the guide belt and of which one side is rotatably installed on the guide body and the other side supports the guide support, a second link coupled to the opening and closing plate, and a third link which connects the first link to the second link.

The first link can include a rotation link of which one side is rotatably installed on the guide body and which can be tilted between a first position at which the display panel assembly is horizontally disposed and a second position at which the display panel assembly is extended below the mounting frame, a connection link of which one side is coupled to one side of the rotation link and a central portion is rotatably coupled to the third link and which can be tilted in conjunction with the rotation link, and a support link of which one side is fixed to the other side of the connection link and the other side supports the guide support.

The guide member can further include a plurality of sensors which is installed on the guide body and senses the rotation link being tilted.

The plurality of sensors can include a first sensor disposed at the first position, and a second sensor disposed at the second position, wherein the first sensor and the second sensor are disposed along a circumferential direction of a circle centering on the one side of the rotation link as a center axis.

The rotation link interacts with any one of the first sensor and the second sensor and a tilting angle of the rotation link can be restricted by one of the first sensor and the second sensor.

The first link, the second link, and the third link can constitute a pivotable four-bar link structure.

An end of the display panel assembly can be coupled to an end of the guide support, and as the guide support is applied with pressure by the display panel assembly applied with pressure by an end of the display panel assembly and increased in length, the guide support guides sliding of the display panel assembly.

The guide support can have a telescopic structure which can be increased in length.

A maximum deployment length of the guide support can be three times to four times greater than a height of the mounting frame.

The guide support can include a main guide plate which includes an accommodation groove on one side, a movable rail on both side portions intersecting the accommodation groove, and a movable block which is coupled to a support link of the guide driver, and can move along the movable rail, a sub-guide plate which includes a driving rail and a driving block movably coupled to the driving rail, has a hollow inside, and is slidably installed in the accommodation groove, and a connection guide plate to which the display panel assembly is fixed and which is slidably installed inside the sub-guide plate, wherein the movable block can be moved along the movable rail by rotation of the rotation link and moves the main guide plate in a direction opposite to a movement direction.

The slidable display device can further comprise a plurality of upper rollers spaced apart from and parallel to each other on one side of the mounting frame, and a plurality of lower rollers which is disposed under the plurality of upper rollers and rotatably supports the display panel assembly together with the plurality of upper rollers.

The plurality of upper rollers and the plurality of lower rollers can be installed above the opening and closing plate on the mounting frame.

The plurality of lower rollers can include a plurality of first lower rollers disposed parallel with respect to the plurality of upper rollers, and a plurality of second lower rollers disposed in a downwardly tilting direction with respect to the plurality of first lower rollers, wherein a bending portion of the display panel assembly can be mounted on the plurality of second lower rollers in conjunction with tilting of the guide member.

The slidable display device can further comprise a panel transfer unit which is disposed on the mounting frame and coupled to the display panel assembly, and slides the display panel assembly.

What is claimed is:

1. A slidable display device comprises:
a display panel assembly;
a mounting frame; and
a guide member tiltably connected to the mounting frame, the guide member being configured to support the display panel assembly as the display panel assembly moves between a first position and a second position with respect to the mounting frame, the guide member being configured to bend the display panel assembly as the display panel assembly moves from the first position to the second position so that a first portion of the display panel assembly is tilted downward.

2. The slidable display device of claim 1, wherein the first portion of the display panel assembly extends past the mounting frame at the second position.

3. The slidable display device of claim 1, wherein the guide member includes:
a guide support connected to the display panel assembly;
a guide body located at one end of the mounting frame; and
a guide driver located at the mounting frame and the guide body.

4. The slidable display device of claim 3, wherein the guide driver further includes a link assembly, the link assembly configured to rotate the guide support and bend the display panel assembly.

5. The slidable display device of claim 4, wherein the guide member further comprises an opening and closing cover connected to the link assembly, the opening and closing cover being configured to rotate with the guide support.

6. The slidable display device of claim 5, wherein the guide driver further includes:
a drive motor located at another end of the mounting frame opposite the one end of the mounting frame;
a motor pulley connected to the drive motor; and
a guide belt connecting the motor pulley to the link assembly, the guide belt being configured to rotate the link assembly.

7. The slidable display device of claim 6, wherein the link assembly includes:
a first link rotatably connected to the guide support at a first end of the first link, the first link having a link pulley connected to the guide belt at a second end of the first link;
a second link connected to the opening and closing plate; and
a third link rotatably connecting the second link to the first link.

8. The slidable display device of claim 7, wherein the guide member further includes a pair of sensors spaced apart from each other, and
wherein the link assembly includes a rotation link connected to the second end of the first link, the rotation link being configured to rotate between the pair of sensors as the display panel assembly moves between the first position and the second position.

9. The slidable display device of claim 3, wherein an end of the display panel assembly is connected to the guide support.

10. The slidable display device of claim 9, wherein the guide support includes:
a main guide plate connected to the link assembly; and
a connection guide plate connected to the end of the display panel assembly, the connection guide plate being configured to be slidable relative to the main guide plate.

11. The slidable display device of claim 10, wherein the guide support includes at least one sub-plate connecting the main guide plate to the connection guide plate, and
wherein the at least one sub-plate and the connection guide plate are configured to be received in a recess at a lower portion of the main guide plate.

12. The slidable display device of claim 10, wherein the guide support includes at least one guide support roller disposed at a lower side of the guide support, the at least one guide support roller being in contact with the display panel assembly.

13. The slidable display device of claim 12, further comprising:
at least one upper roller at an upper portion of the one end of the mounting frame; and
at least one lower roller at a lower portion of the one end of the mounting frame,
wherein the at least one upper roller and the at least one guide support roller are configured to contact an upper surface of the display panel assembly, and
wherein the at least one lower roller is configured to contact a lower surface of the display panel assembly.

14. The slidable display device of claim 1, further comprising a panel transfer unit connected to the mounting frame and the display panel assembly, the panel transfer unit being configured to apply a force to the display panel assembly to move the display panel assembly between the first position and the second position.

15. The slidable display device of claim 14, wherein the panel transfer unit includes:
a drive motor;
a rotary shaft connected to the drive motor; and
a carrier configured to reciprocate between a first end of the rotary shaft and a second end of the rotary shaft, the carrier being connected to the display assembly panel.

16. A roof panel assembly for a vehicle, the roof panel assembly comprising:
a roof panel having an opening; and
a slidable display device connected to the roof panel assembly, the slidable display device including:
a display panel assembly;
a mounting frame connected to the roof panel; and
a guide member tiltably connected to the mounting frame, the guide member being configured to support the display panel assembly as the display panel assembly moves between a first position above the roof panel and a second position in which a portion of the display panel assembly is tilted downward to extend through the opening of the roof panel.

17. The roof panel assembly of claim 16, wherein the guide member includes:
a guide support connected to the display panel assembly;
a guide body located at one end of the mounting frame; and
a guide driver located at the mounting frame and the guide support to the guide body.

18. The roof panel assembly of claim 17, wherein the guide driver further includes a link assembly, the link assembly configured to rotate the guide support and bend the display panel assembly.

19. The roof panel assembly of claim 18, wherein the guide member further comprises an opening and closing cover connected to the link assembly, the opening and closing cover being configured to rotate with the guide support to at least partially open and close the opening of the roof panel.

20. The roof panel assembly of claim 17, further comprising a panel transfer unit connected to the mounting frame and the display panel assembly, the panel transfer unit being configured to apply a force to the display panel assembly to move the display panel assembly between the first position and the second position.
